(19) United States
(12) Patent Application Publication
(10) Pub. No.: US 2012/0024586 A1
(43) Pub. Date: Feb. 2, 2012

(54) PRINTED WIRING BOARD, METHOD FOR MANUFACTURING THE SAME, AND ELECTRONIC EQUIPMENT

(75) Inventors: Hideaki YOSHIMURA, Kawasaki (JP); Kenji IIDA, Kawasaki (JP); Yasutomo MAEHARA, Kawasaki (JP)

(73) Assignee: FUJITSU LIMITED, Kawasaki-shi (JP)

(21) Appl. No.: 13/097,530

(22) Filed: Apr. 29, 2011

(30) Foreign Application Priority Data
Jul. 28, 2010 (JP) 2010-169846

(51) Int. Cl. H05K 1/11; H01K 3/10

(52) U.S. Cl. 174/264; 29/852

(57) ABSTRACT

A printed wiring board including a substrate that includes wiring through-hole portions where wiring through-holes which each penetrate the substrate from a surface on a front side of the substrate to a surface on a back side of the substrate, the wiring through-hole portions being made using a dielectric material having a thermal expansion coefficient different from a thermal expansion coefficient of the substrate; and thermal-expansion adjusting portions produced by filling prepared-holes with the dielectric material, the prepared-holes being produced at a surface of the substrate. The surface is partitioned into predetermined blocks, in each of which the thermal-expansion adjusting portions are placed in a layout that minimizes a difference between a thermal expansion coefficient in the block in a length direction and a thermal expansion coefficient in the block in a width direction according to a placement of the wiring through-hole portions in the block.

### CROSS-REFERENCE TO RELATED APPLICATION

This application is based upon and claims the benefit of priority of the prior Japanese Patent Application No. 2010-169846, filed on Jul. 28, 2010, the entire contents of which are incorporated herein by reference.

### FIELD

The embodiments discussed herein are directed to a printed wiring board, a method for manufacturing the same, and an electronic equipment.

### BACKGROUND

A typical thermal expansion coefficient of a printed wiring board where large scale integration (LSI) packaging is implemented is approximately 17 ppm/° C., matched to a thermal expansion efficient of a copper lead material used in patterning. However, in actuality, printed wiring boards with low thermal expansion coefficients of approximately 3 to 3.5 ppm/° C. close to that of silicon wafers are demanded in recent years.

Under such circumstances, a substrate of a printed wiring board is typically made together with FR4, FR5, or FR6 (grade designation of flame retardancy of a copper-clad laminate, which is a member of a printed wiring board; “FR” means flame retardant) or a prepreg obtained by impregnation with resin, such as bismaleimide-triazine range (BT range), having a low thermal expansion coefficient. Glass fiber, such as T-glass fiber, having a low thermal expansion coefficient (thermal expansion coefficient: approximately 3 ppm/° C.; elastic modulus: approximately 80 GPa) is employed rather than E-glass fiber (thermal expansion coefficient: approximately 5.5 ppm/° C.; elastic modulus: approximately 70 GPa) which is generally employed as a fiber material to be impregnated to produce a prepreg. Put another way, an attempt of reducing the thermal expansion coefficient of a substrate of a printed wiring board (PWB) has been made by appropriately selecting a prepreg or fiber to be impregnated to obtain a prepreg. However, such a PWB substrate as that discussed above typically has a thermal expansion coefficient substantially equal to or greater than 12 ppm/° C., which makes it difficult to achieve a thermal expansion coefficient close to that of silicon wafers.

As a scheme for further improvement, a scheme of manufacturing a substrate by using, in lieu of glass fiber, a prepreg obtained by impregnating organic fiber, such as aramid fiber, or inorganic fiber, such as carbon fiber, having a high elastic modulus higher than approximately 100 GPa and a low thermal expansion coefficient equal to or 1 ppm/° C. with resin is known. A scheme of manufacturing a core material of a printed wiring board by using, in lieu of organic fiber or inorganic fiber, a plate of alloy, such as Invar, having a low thermal expansion coefficient is also known. Meanwhile, organic fiber is a dielectric material whereas inorganic fiber and a plate of alloy, such as Invar, are conductive materials.

A printed wiring board, to which an improving scheme mentioned previously is applied, is described below. FIG. 11 is a cross-sectional view of a conventional printed wiring board 100A including a substrate 101A of a conductive material. The printed wiring board 100A illustrated in FIG. 11 includes the substrate 101A made using a conductive material, such as inorganic fiber, e.g., carbon fiber or Invar, having a low thermal expansion coefficient. The printed wiring board 100A desirably has a configuration for insulating, from the substrate 101A, through holes 103A that provide electrical connection between wiring layers 102A because the substrate 101A is a conductive material. Accordingly, the printed wiring board 100A has a double structure, in which large prepared-holes 104A are defined at portions where the through holes 103A are provided, and the prepared-holes 104A are filled with resin 105A, such as epoxy, to insulate electrical connection between the substrate 101A and the through holes 103A with the resin 105A.

FIG. 12 is a cross-sectional view of a conventional printed wiring board 100B that includes a substrate 101B made using a dielectric material. The printed wiring board 100B illustrated in FIG. 12 includes the substrate 101B of a dielectric material having a low thermal expansion coefficient, such as organic fiber, e.g., aramid fiber. It is not necessary for the printed wiring board 100B to insulate, from the substrate 101B, through holes 103B that provide electrical connection between wiring layers 102B because the substrate 101B is a dielectric material. With the printed wiring board 100B, a need of filling the through holes 103B in the substrate 101B with resin 105B, such as epoxy, arises to laminate a build-up wiring layer 106B on the wiring layer 102B.

However, with the conventional printed wiring board 100A, 100B, a thermal expansion coefficient of the substrate 101A, 101B differs largely from a thermal expansion coefficient of the filler resin 105A, 105B and a thermal expansion coefficient at plated portions of the through holes 103A, 103B where inner peripheral walls are plated with copper or the like. For instance, the thermal expansion coefficient of the substrate 101A, 101B is approximately 1 ppm/° C. whereas the thermal expansion coefficient of the filler resin 105A, 105B is approximately 30 ppm/° C. and the thermal expansion coefficient of the copper plated on the walls is approximately 17 ppm/° C. Consequently, the printed wiring board 100A, 100B has considerably high thermal expansion coefficient at portions where the through holes 103A, 103B are provided.

A scheme of adding an inorganic filler, such as silica powder, having a low thermal expansion coefficient can be employed to lower the thermal expansion coefficient of resin, such as epoxy, used as the filler. However, there is an upper limit for an amount of the inorganic filler that can be added. A scheme of adding, to the filler, a fibrous material capable of considerable improvement in characteristics even when an addition amount of the fibrous material is modest and placing the filler mixed with the fibrous material in directions along the surfaces of the through holes 103A, 103B can be employed; however, this scheme is not appropriate for ultra-fine through holes, which makes it difficult to obtain a filler appropriate for a substrate having a low thermal expansion coefficient.

More specifically, if there are high-density areas where through hole density is high and low-density areas where through hole density is low on a surface of a workpiece during manufacturing of the conventional printed wiring board 100A, 100B, a wide difference can develop between a thermal expansion coefficient in the high-density areas and that in the low-density areas. As a result, warpage, twist, or the like deformation can occur in the surface of the workpiece during hot pressing or the like involved in a laminating process or the like that is to be performed during manufacturing of the printed wiring board. Furthermore, the manufactured product can be permanently deformed, or, more particularly, warped or twisted, because of temperature changes that occur during heat curing involved in manufacturing.

### SUMMARY

According to an aspect of an embodiment of the invention, a printed wiring board including a substrate that includes wiring through-hole portions where wiring through-holes which each penetrate the substrate from a surface on a front side of the substrate to a surface on a back side of the substrate, the wiring through-hole portions being made using a dielectric material having a thermal expansion coefficient different from a thermal expansion coefficient of the substrate; and thermal-expansion adjusting portions each produced by filling a prepared-hole with the dielectric material, the prepared-holes being produced at a surface of the substrate. The surface is partitioned into predetermined blocks, in each of which the thermal-expansion adjusting portions are placed in a layout that minimizes a difference between a thermal expansion coefficient in the block in a length direction and a thermal expansion coefficient in the block in a width direction according to a placement of the wiring through-hole portions in the block.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is a cross-sectional view of a printed wiring board according to an embodiment of the present invention;

FIG. 2 is an external plan view illustrating a surface of a substrate used in the printed wiring board according to the embodiment;

FIG. 3 is an explanatory diagram illustrating a surface where wiring through-hole portions and thermal-expansion adjusting portions are placed of the substrate;

FIGS. 4A to 4H illustrate processes for manufacturing the printed wiring board according to the embodiment;

FIGS. 5A to 5C illustrate example layouts of the wiring through-hole portions and the thermal-expansion adjusting portions in a square cell;

FIGS. 6A and 6B illustrate example layouts of the wiring through-hole portions and the thermal-expansion adjusting portions in a rectangular cell;

FIG. 7 is a cross-sectional view of a six-layer printed wiring board;

FIG. 8 is a cross-sectional view of a build-up circuit board;

FIG. 9 is a cross-sectional view of another build-up circuit board;

FIG. 10 is a cross-sectional view of a build-up wiring board including a substrate of a dielectric material;

FIG. 11 is a cross-sectional view of a conventional printed wiring board including a substrate of a conductive material; and

FIG. 12 is a cross-sectional view of a conventional printed wiring board including a substrate of a dielectric material.

### DESCRIPTION OF EMBODIMENTS

Preferred embodiments of the present invention will be explained with reference to accompanying drawings. Note that the embodiments are not intended to limit the scope of the present invention.

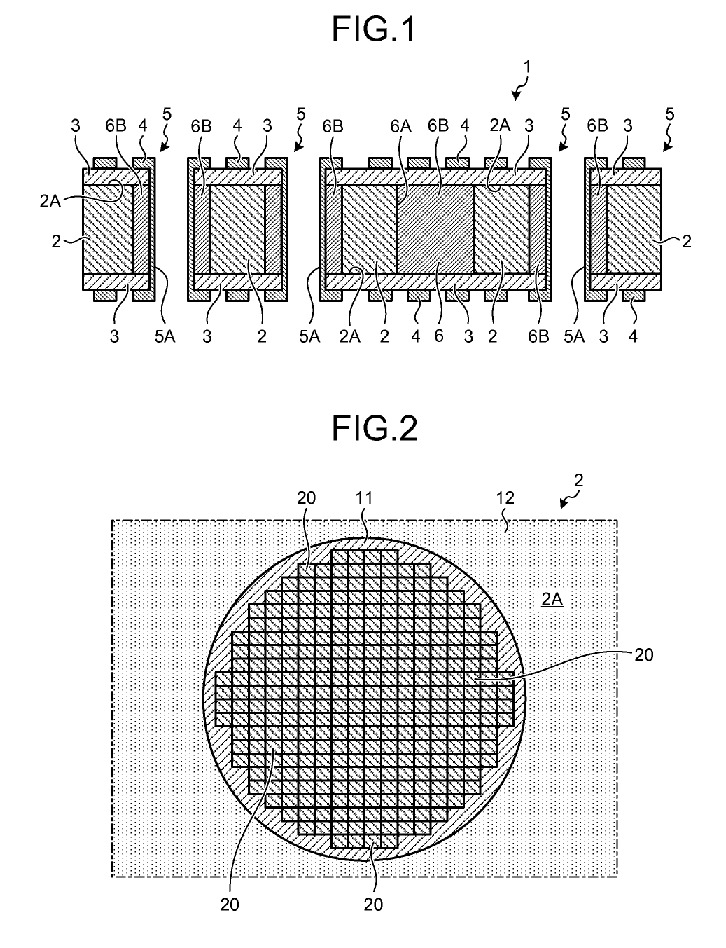

FIG. 1 is a cross-sectional view of a printed wiring board 1 according to an embodiment of the present invention. The printed wiring board 1 illustrated in FIG. 1 includes a substrate 2, wiring layers 3 laminated on a front surface and a back surface of the substrate 2, and wiring patterns 4 formed on the wiring layers 3. The printed wiring board 1 further includes wiring through-hole portions across surfaces 2A of the substrate 2 and thermal-expansion adjusting portions 6 between surfaces 2A. The wiring through-hole portions 5 are portions where wiring through holes 5A passing through from the surface 2A on the front side to the surface 2A on the back side of the substrate 2 are provided. The wiring through-hole portions 5 are formed using a dielectric material 6B having a thermal expansion coefficient different from that of the substrate 2. The thermal-expansion adjusting portions 6 are portions where prepared-holes 6A defined between the surfaces 2A of the substrate 2 are provided. The thermal-expansion adjusting portions 6 are produced by filling the prepared-holes 6A with the dielectric material 6B.

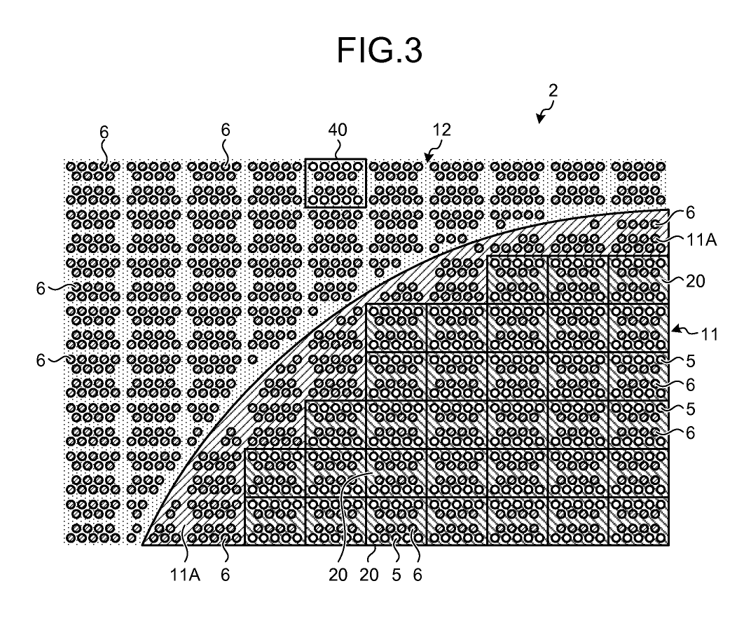

FIG. 2 is an external plan view illustrating of the surface 2A of the substrate 2 used in the printed wiring board 1 according to the embodiment. FIG. 3 is an explanatory diagram illustrating the surface 2A, of the substrate 2, where the wiring through-hole portions 5 and the thermal-expansion adjusting portions 6 are provided. For explanatory purposes, the wiring through-hole portions 5 and the thermal-expansion adjusting portions 6 are indicated by white circles and black circles, respectively, in FIG. 3. The surface 2A of the substrate 2 illustrated in FIG. 2 has a product area 11 and an other-than-product area 12. The product area 11 is partitioned into a plurality of cells 20 corresponding to predetermined blocks. The wiring through-hole portions 5 and the thermal-expansion adjusting portions 6 are placed in each of the cells 20. The thermal-expansion adjusting portions 6 are placed in a layout that minimizes a difference between a thermal expansion coefficient in the length direction and that in the width direction (hereinafter, “length/width-direction difference in thermal expansion coefficient”) in the cell 20 to, for instance, “zero” according to a placement of the wiring through-hole portions 5 in the cell 20.

In the other-than-product area 12, the thermal-expansion adjusting portions 6 are placed in the same layout as the layout of the wiring through-hole portions 5 and the thermal-expansion adjusting portions 6 in the cells 20 so that the other-than-product area 12 have the same thermal expansion coefficients in the width direction and in the length direction (hereinafter, “length/width-direction thermal expansion coefficients”) as those in the cells 20 in the product area 11. A test coupon pattern 40 for product assurance of the wiring through-hole portions 5 and the thermal-expansion adjusting portions 6 is formed on the other-than-product area 12. In the test coupon pattern 40, the wiring through-hole portions 5 and the thermal-expansion adjusting portions 6 are placed in the same layout as the layout of the wiring through-hole portions 5 and the thermal-expansion adjusting portions 6 in the cells 20 in the product area 11.

The product area 11 includes a to-be-removed area 11A, being an area other than the cells 20. In the to-be-removed area 11A, the thermal-expansion adjusting portions 6 are placed in a same pattern as a pattern of the wiring through-hole portions 5 and the thermal-expansion adjusting portions 6 in the cells 20 so that the to-be-removed area 11A have same length/width-direction thermal expansion coefficients as those in the cells 20.

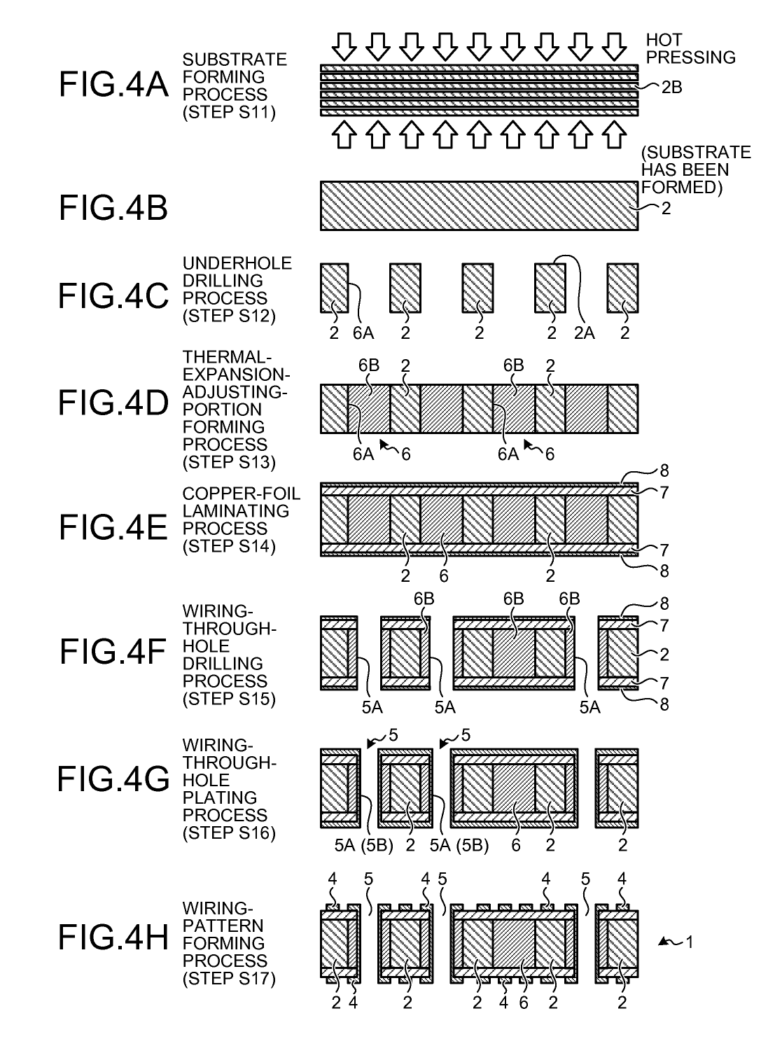

Processes for manufacturing the printed wiring board 1 are described in detail below. FIG. 4 is an explanatory diagram illustrating the processes for manufacturing the printed wiring board 1 according to the embodiment. At a layout design process, a layout design that places the thermal-expansion adjusting portions 6 in each of the cells 20 according to a placement of the wiring through-hole portions 5 in the cell 20 to thereby minimize the length/width-direction difference in thermal expansion coefficient in the cell 20 provided by partitioning the surface 2A of the substrate 2 is created. The layout design is also created so as to place the thermal-expansion adjusting portions 6 in the other-than-product area 12 and in the to-be-removed area 11A in the same layout as the layout of the wiring through-hole portions 5 and the thermal-expansion adjusting portions 6 in the cell 20 so that the other-than-product area 12 and in the to-be-removed area 11A have the same length/width-direction thermal expansion coefficients as those in the cells 20.

At a substrate forming process (Step S11), a plurality of prepreg layers 2B are laminated, and the thus-laminated prepreg layers 2B undergo hot pressing to form the substrate 2. The prepreg layer 2B can be a woven cloth of carbon fiber impregnated with resin and processed to a B stage. Examples of the carbon fiber include fiber having a thermal expansion coefficient of approximately 0 ppm/° C. and an elastic modulus of approximately 370 GPa. Even when this carbon fiber is processed to become a carbon fiber reinforced plastic (CFRP) by application of resin for use in FR-4 or the like thereonto and curing, the thus-obtained CFRP exhibits, as physical properties, thermal expansion coefficient of approximately 0 ppm/° C. and an elastic modulus of approximately 80 GPa.

At an prepared-hole drilling process (Step S12), the prepared-holes 6A are drilled between the surfaces 2A of the substrate 2 according to the layout design created at the layout designing process. The prepared-holes 6A are, for instance, 0.8 mm in diameter. To prevent resin from being contaminated with carbon chippings produced during drilling the prepared-holes 6A, the inner peripheral walls of the prepared-holes 6A are plated with copper in thickness of 25 μm.

At a thermal-expansion-adjusting-portion forming process (Step S13), the prepared-holes 6A between the surfaces 2A of the substrate 2 are filled with the dielectric material 6B, serving as filler, thereby producing the thermal-expansion adjusting portions 6 in the surfaces 2A. Examples of the dielectric material 6B, serving as filler, include resin, in which silica filler is mixed to reduce the thermal expansion coefficient, having a thermal expansion coefficient of approximately 33 ppm/° C. and an elastic modulus of approximately 4.7 GPa. A part of the dielectric material 6B lying off the surface 2A of the substrate 2 is ground to level the surface 2A.

At a copper-foil laminating process (Step S14), a copper foil 8 is laminated on each of the front surface and the back surface of the substrate 2, in which the thermal-expansion adjusting portions 6 are produced, by using a prepreg 7 of FR4. The prepreg 7 is preferably a prepreg containing glass fiber to prevent exposure of carbon fiber.

At a wiring-through-hole drilling process (Step S15), the wiring through holes 5A are drilled through from the front surface to the back surface at portions corresponding to the wiring through-hole portions 5, which are portions filled with the dielectric material 6B, according to the layout design.

At a wiring-through-hole plating process (Step S16), the inner peripheral walls of the thus-drilled wiring through holes 5A are plated with copper to apply copper plating 5B having a thermal expansion coefficient of approximately 17 ppm/° C., thereby forming the wiring through-hole portions 5 in each of the cells 20. The wiring through-hole portions 5 provide electrical connection between the front surface and the back surface of the substrate 2.

At a wiring-pattern forming process (Step S17), after the inner peripheral walls of the wiring through hole 5A are covered with the copper plating 5B, a dry film resist is applied onto the copper foil 8. At the wiring-pattern forming process (Step S17), the wiring patterns 4 are formed on the surfaces 2A by etching the wiring patterns 4 onto the copper foils 8 on the surfaces 2A of the substrate 2. As a result, the printed wiring board 1, which is double sided, having a thermal expansion coefficient of approximately 3 to 7 ppm/° C. is obtained.

Actual measurement of the thermal expansion coefficients in the cell 20 is performed by building a trial piece of the product area 11 of the substrate 2 and measuring the thermal expansion coefficients in the cell 20, in which only the wiring through-hole portions 5 are placed, in the product area 11. Results of the measurement are as follows: X=6.5 ppm/° C.; Y=7.9 ppm/° C.; and Δ=1.4 ppm/° C., where X is the thermal expansion coefficient in the cell 20 in the width direction, Y is the thermal expansion coefficient in the cell 20 in the length direction, and Δ is the length/width-direction difference in thermal expansion coefficient in the cell 20. Similarly, actual measurement of thermal expansion coefficients in the cell 20 is performed by measuring the thermal expansion coefficients in the cell 20, in which the thermal-expansion adjusting portions 6 are placed in a layout that narrows the length/width-direction difference in thermal expansion coefficient in the cell 20 according to the placement of the wiring through-hole portions 5 in the cell 20. Results of the measurement in this cell 20 are as follows: X=6.3 ppm/° C.; Y=7.0 ppm/° C.; and Δ=0.7 ppm/° C.

This indicates that the configuration according to an aspect of the present invention can narrow the length/width-direction difference in thermal expansion coefficient in the cell 20. Meanwhile, the length/width-direction difference in thermal expansion coefficient in the cell 20 can be brought to a value approximately “zero” by increasing precision in placement. Furthermore, placing the thermal-expansion adjusting portions 6 in the other-than-product area 12 and in the to-be-removed area 11A in the same layout as the layout of the wiring through-hole portions 5 and the thermal-expansion adjusting portions 6 in the cell 20, can reduce product warpage to approximately 0.2 mm as compared to warpage of approximately 0.4 mm, which is typical warpage of a product where the thermal-expansion adjusting portions 6 are not placed. Thus, product warpage can be reduced in half.

When the substrate 2 whose actual working size is 510 mm×340 mm is used in manufacturing and the thermal-expansion adjusting portion 6 is not placed in each of the other-than-product area 12 and the to-be-removed area 11A, the thermal expansion coefficient in the other-than-product area 12 and the to-be-removed area 11A is approximately 5 ppm/° C.; the thermal expansion coefficient in the product area 11 is approximately 7 ppm/° C. Hence, placing the thermal-expansion adjusting portions 6 only in the product area 11 causes warpage of approximately 20 mm to occur in a product during manufacturing.

In contrast, placing the thermal-expansion adjusting portions 6 not only in the product area 11 but also in the other-than-product area 12 and the to-be-removed area 11A in the same layout as the layout of the wiring through-hole portions 5 and the thermal-expansion adjusting portions 6 in the cell 20 in the product area 11 has reduced warpage, that occurs during manufacturing, to approximately several millimeters. Hence, this configuration can reduce product warpage that can occur during manufacturing of a substrate.

Accordingly, in the embodiment, the thermal-expansion adjusting portions 6 are placed in the cells 20 according to the placement of the wiring through-hole portions 5 in the cells 20 so as to minimize the length/width-direction difference in thermal expansion coefficient in the cells 20 provided by partitioning the surface 2A of the substrate 2. This makes the thermal expansion coefficients in the cells 20 in the substrate 2 uniform, thereby preventing the product from being deformed by warpage or twisting, which can occur in a product manufactured using a conventional technique.

Furthermore, in the embodiment, the thermal-expansion adjusting portions 6 are placed in each of the product area 11, the to-be-removed area 11A, and the other-than-product area 12 so as to minimize the differences among the product area 11, the to-be-removed area 11A, and the other-than-product area 12 in length/width-direction thermal expansion coefficients. This prevents product deformation, such as warpage or twisting, which can occur in a product manufactured using a conventional technique.

In the embodiment, the thermal-expansion adjusting portions 6 are filled with the dielectric material 6B. Accordingly, an undesirably situation that wiring density of the wiring pattern 4 is decreased by the thermal-expansion adjusting portions 6 can be avoided.

In the embodiment, the number of the thermal-expansion adjusting portions 6 placed in the cell 20 is adjusted so as to make a distribution density of the wiring through-hole portions 5 and the thermal-expansion adjusting portions 6 in the cell 20 uniform so that the length/width-direction difference in thermal expansion coefficient in the cell 20 is minimized. Because the distribution density of the wiring through-hole portions 5 and that of the thermal-expansion adjusting portions 6 are of a same size, the thermal expansion coefficients in the cell 20 can be adjusted by adjusting the number of the thermal-expansion adjusting portions 6 placed in the cell 20.

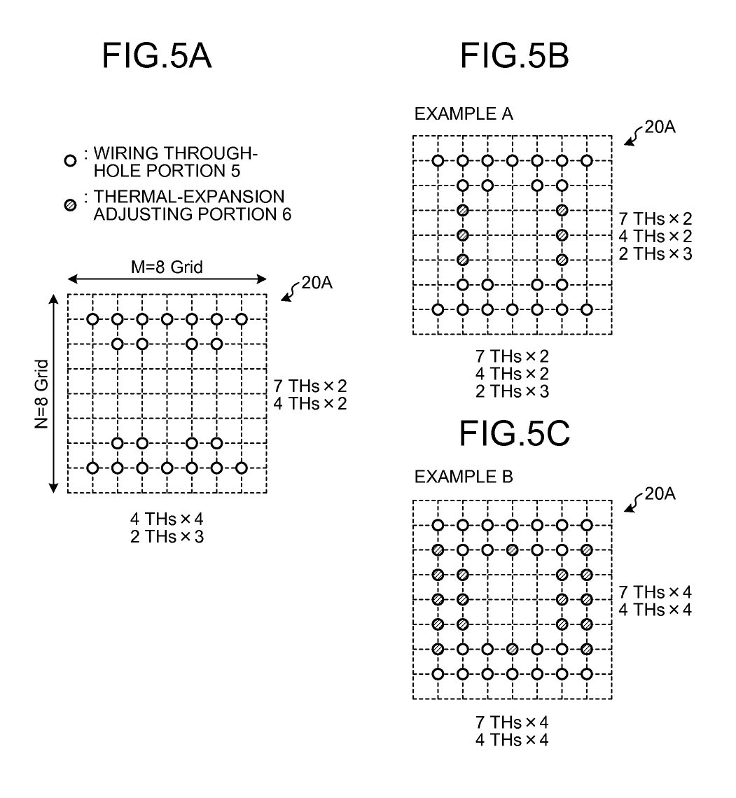

In the embodiment, the cells 20 are discussed as being the predetermined blocks. The cells 20 can be square cells. How to place the thermal-expansion adjusting portions 6 in an example situation where the cell 20 is a square cell having columns (N=8 grid) and rows (M=8 grid) is described below. FIG. 5 is an explanatory diagram illustrating an example layout of the wiring through-hole portions 5 and the thermal-expansion adjusting portions 6 in a square cell 20A. The wiring through-hole portions 5 (white circles) are placed in the square cell 20A. The numbers of columns (hereinafter, “per-placed-number column counts”), each being number of columns where a same number of the wiring through-hole portions 5 are placed in the square cell 20A are determined based on per-column-basis counts of the wiring through-hole portions 5 in the square cell 20A. The per-placed-number column counts of the example illustrated in FIG. 5 are as follows: the number of columns, on each of which the wiring through-hole portions 5 are placed at two points, is three (2 THs×3), and the number of columns, on each of which the wiring through-hole portions 5 are placed at four points, is four (4 THs×4). The number of rows, on each of which the wiring through-hole portions 5 are placed at seven points, in the square cell 20A is also determined based on per-row-basis counts of the wiring through-hole portions 5 in the square cell 20A. The per-placed-number row counts of the example illustrated in FIG. 5 are as follows: the number of rows, on each of which the wiring through-hole portions 5 are placed at seven points, is two (7 THs×2), and the number of rows, on each of which the wiring through-hole portions 5 are placed at four points, is two (4 THs×2).

To make the distribution density of the wiring through-hole portions 5 and the thermal-expansion adjusting portions 6 placed in the square cell 20A uniform, the thermal-expansion adjusting portions 6 are desirably placed in the square cell 20A in a placement that makes the per-placed-number column counts equal to the per-placed-number row counts in the square cell 20A.

In the example A illustrated in FIG. 5, the thermal-expansion adjusting portions 6 (black circles) are placed in the square cell 20A in a placement that makes per-placed-number column counts equal to per-placed-number row counts, or, more specifically, such that each of the per-placed-number column counts and the per-placed-number row counts are 7 THs×2, 4 THs×2, and 2 THs×3. In the example B illustrated in FIG. 5, the thermal-expansion adjusting portions 6 (black circles) are placed in the square cell 20A in a placement that makes each of the per-placed-number column counts and the per-placed-number row counts 7 THs×4 and 4 THs×4.

Put another way, as for the square cell 20A, the thermal-expansion adjusting portions 6 are additionally placed in a placement that makes the per-placed-number row counts equal to the per-placed-number column counts in the square cell 20A according to the layout of the wiring through-hole portions 5 in the square cell 20A. This makes the distribution density of the wiring through-hole portions 5 and the thermal-expansion adjusting portions 6 in the square cells 20A uniform, thereby narrowing the length/width-direction difference in thermal expansion coefficient to minimum.

The thermal-expansion adjusting portions 6 are placed at 6 points in the example A of FIG. 5, whereas the thermal-expansion adjusting portions 6 are placed at 18 points in the example B of FIG. 5. The greater the number of the thermal-expansion adjusting portions 6, the higher the thermal expansion coefficient. Accordingly, the number of the thermal-expansion adjusting portions 6 is desirably small.

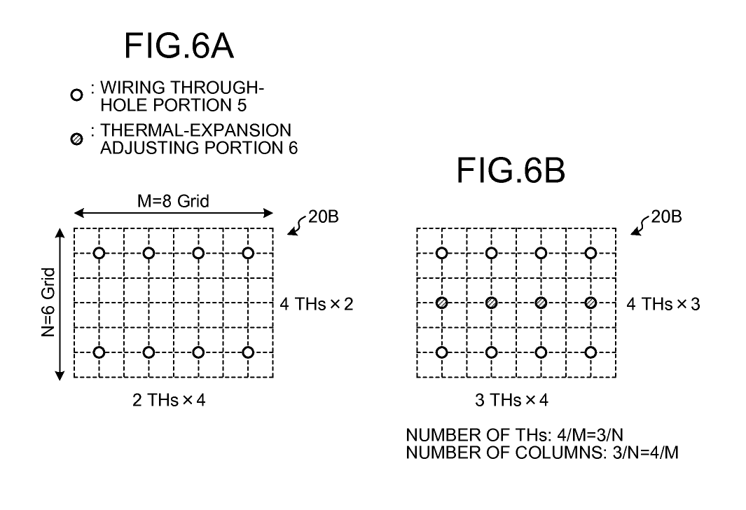

A layout of the thermal-expansion adjusting portions 6 in an example situation where the cell 20 is a rectangular cell having columns (N=6 grid) and rows (M=8 grid) is described below. FIG. 6 is an explanatory diagram illustrating an example layout of the wiring through-hole portions 5 and the thermal-expansion adjusting portions 6 in a rectangular cell 20B. The wiring through-hole portions 5 (white circles) are placed in the rectangular cell 20B. In the rectangular cell 20B illustrated in FIG. 6, the number of rows, on each of which the wiring through-hole portions 5 are placed at two points, is four (2 THs×4). In the rectangular cell 20B, the number of rows, on each of which the wiring through-hole portions 5 are placed at four points, is two (4 THs×2).

The thermal-expansion adjusting portions 6 are additionally placed, according to the layout of the wiring through-hole portions 5, in the rectangular cell 20B in a placement that makes a spacing between the columns of the wiring through-hole portions 5 of the rectangular cell 20B equal to a spacing between the rows of the wiring through-hole portions 5 in the rectangular cell 20B. As illustrated in FIG. 6, consequently, the number of columns, on each of which the wiring through-hole portions 5 and the thermal-expansion adjusting portions 6 are placed at three points, is four (3 THs×4) and the number of rows, on each of which the wiring through-hole portions 5 and the thermal-expansion adjusting portions 6 are placed, at four points is three (4 THs×3).

Thus, as for the rectangular cell 20B, the thermal-expansion adjusting portions 6 are additionally placed in a placement that makes the spacing between the columns of the wiring through-hole portions 5 of the rectangular cell 20B equal to a lead pitch in the rows of the wiring through-hole portions 5 in the rectangular cell 20B. This makes the distribution density of the wiring through-hole portions 5 and the thermal-expansion adjusting portions 6 in the rectangular cell 20B uniform, thereby narrowing the length/width-direction difference in thermal expansion coefficient to minimum.

In the discussion, the thermal expansion coefficients are adjusted by adjusting the number of the thermal-expansion adjusting portions 6 to be placed; alternatively, the volume of the thermal-expansion adjusting portion 6 to be placed in the cell 20 can be adjusted so as to make the distribution density of the wiring through-hole portions 5 and the thermal-expansion adjusting portions 6 in the cells 20 uniform. Thus, by adjusting the volume of the thermal-expansion adjusting portion 6, even in a situation where the distribution density of the wiring through-hole portions 5 and the thermal-expansion adjusting portions 6 varies, thermal expansion coefficient to be adjusted.

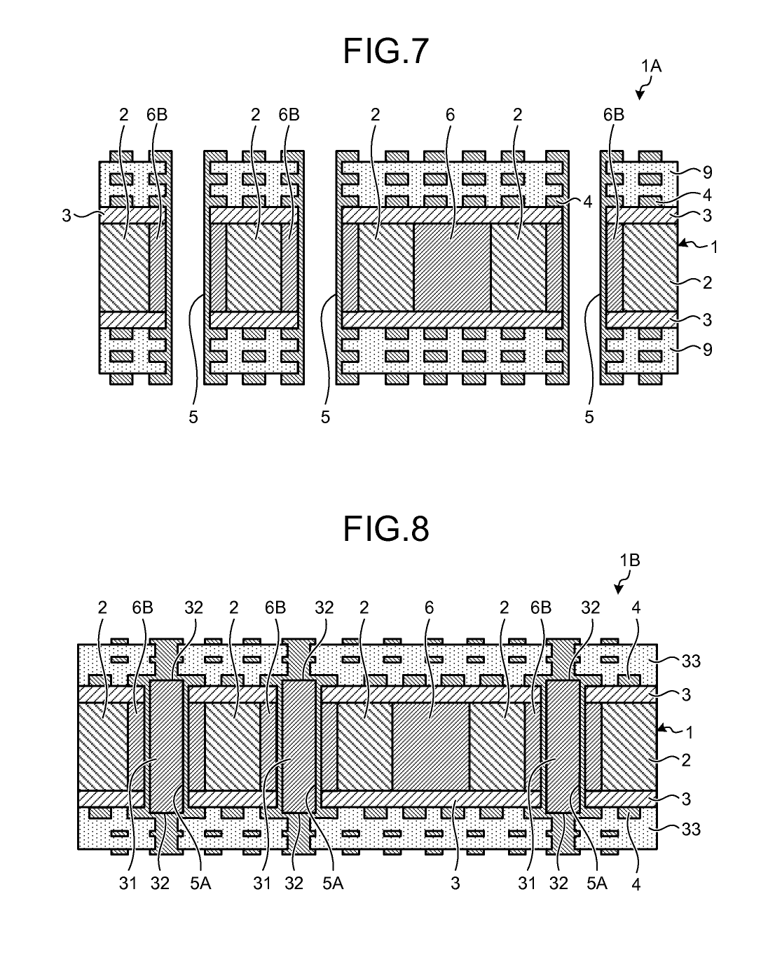

The embodiment has been discussed by way of the example of the printed wiring board 1, which is double sided as illustrated in FIG. 1; however, the embodiment is applicable to a multi-layer printed wiring board. FIG. 7 is a cross-sectional view of a six-layer printed wiring board 1A. Like elements or parts to those of the printed wiring board 1 illustrated in FIG. 1 are designated by like reference numerals, and repeated descriptions about configurations and operations are omitted. The six-layer printed wiring board 1A illustrated in FIG. 7 is constructed to have six layers by laminating a copper foil, onto which the wiring pattern 4 is etched, on each of the front surface and the back surface of the double-sided printed wiring board 1, and laminating a prepreg on the copper foil with a double-sided copper-plated plate 9, on which circuit is formed, interposed therein. Hence, the present embodiment is applicable also to the six-layer printed wiring board 1A.

FIG. 8 is a cross-sectional view of a build-up wiring board 1B. Like elements or parts to those of the printed wiring board 1 illustrated in FIG. 1 are designated by like reference numerals, and repeated descriptions about configurations and operations are omitted. The build-up wiring board 1B illustrated in FIG. 8 is constructed by filling the wiring through holes 5A drilled through the double-sided printed wiring board 1, applying lid plating 32 onto the thus-filled wiring through holes 5A, and thereafter laminating build-up wiring layers 33 on the wiring patterns 4. Hence, the present embodiment is applicable also to the build-up wiring board 1B.

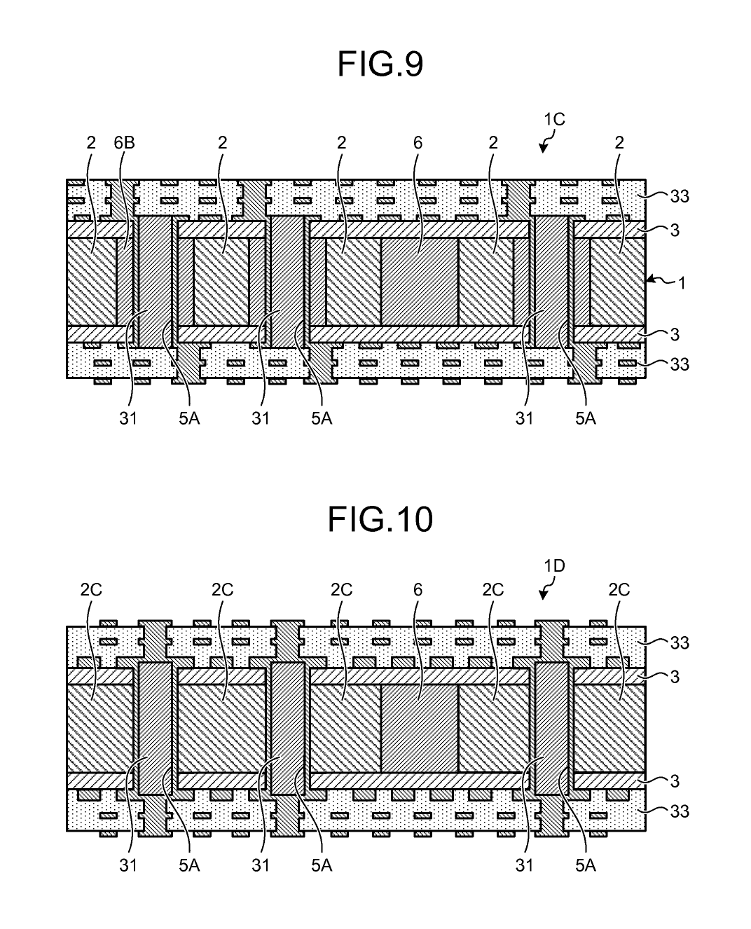

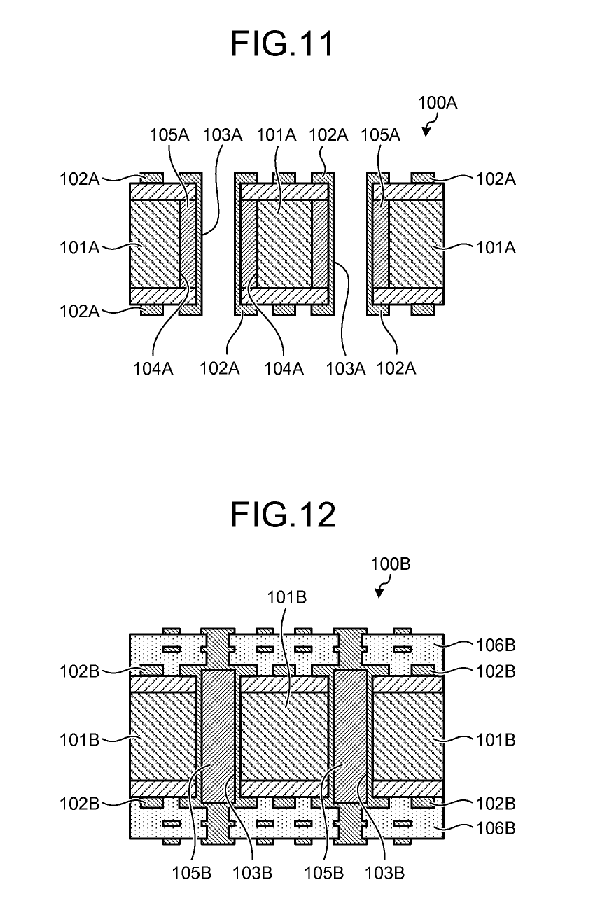

FIG. 9 is a cross-sectional view of a build-up wiring board 1C. Like elements or parts to those of the printed wiring board 1 illustrated in FIG. 1 are designated by like reference numerals, and repeated descriptions about configurations and operations are omitted. The build-up wiring board 1C illustrated in FIG. 9 is constructed by filling the wiring through holes 5A drilled through the double-sided printed wiring board 1 and thereafter laminating the built-up wiring layers 33 on the wiring patterns 4. Hence, the present embodiment is applicable also to the build-up wiring board 1C.

Examples where the printed wiring board 1 illustrated in FIG. 1, and FIG. 7 to FIG. 9 includes the substrate 2 made using the conductive material have been discussed; alternatively, the substrate 2 can be made using a dielectric material. FIG. 10 is a cross-sectional view of a build-up wiring board 1D including a substrate 2C made using a dielectric material. Like elements or parts are designated by like reference numerals to those of the build-up wiring board 1B illustrated in FIG. 8, and repeated descriptions about configurations and operations are omitted. The substrate 2C, being a dielectric material, includes a prepreg that includes, as stuff for controlling thermal expansion, a woven cloth or a non-woven cloth of organic fiber of any one of aramid fiber, poly(p-phenylenebenzobisoxazole), and aromatic polyester fiber. It is not essential for the build-up wiring board 1D to include the dielectric material 6B for use in insulating electrical connection between the wiring through holes 5A and the substrate 2C because the substrate 2C is the dielectric material. Hence, the present embodiment is applicable also to the build-up wiring board 1D.

In the embodiment, the wiring through-hole portion 5 and the thermal-expansion adjusting portion 6 placed on the surface 2A of the substrate 2 are assumed to be equal to each other in size; however, they are not necessarily of a same size so long the wiring through-hole portion 5 and the thermal-expansion adjusting portion 6 are equal to each other in volume.

In the embodiment, the prepared-holes 6A in the thermal-expansion adjusting portions 6 are through holes passing from the surface 2A on the front side to the surface 2A on the back side of the substrate 2; alternatively, the prepared-holes 6A can be holes each having a bottom.

In the embodiment, the substrate 2 includes the prepreg material 2B, being a conductive material, that includes a woven cloth or a non-woven cloth of inorganic fiber of carbon fiber as stuff for controlling thermal expansion. Alternatively, the prepreg 2B, being a conductive material, that includes 42 alloy or Kovar as the stuff for controlling thermal expansion can be employed.

In the embodiment, the thermal-expansion adjusting portions 6 are additionally placed in the cell 20 so as to minimize the length/width-direction difference in thermal expansion coefficient in the cell 20, corresponding to the predetermined block, according to the placement of the wiring through-hole portions 5 in the cell 20. However, the predetermined block is not limited to the cell 20; the predetermined block can alternatively be a predetermined number of cells 20, the product area 11, or the surface 2A of the substrate 2.

The embodiment has been discussed by way of the example of the printed wiring board 1; however, the embodiment is also applicable to a probe card that tests the printed wiring board 1.

In the embodiment, numerical values pertaining to thermal expansion coefficients, elastic modulli, dimensions, and the like are specifically described; however, it should be understood that these numerical values are only exemplary of the present invention, and are not intended to limit the scope of the present invention.

According to an aspect of the present invention, warpage or twist of a product, which may otherwise be caused by a variation in thermal expansion coefficient of a printed wiring board can be advantageously prevented.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed wiring board comprising a substrate, the substrate including:
wiring through-hole portions where wiring through-holes which each penetrate the substrate from a surface on a front side of the substrate to a surface on a back side of the substrate, the wiring through-hole portions being made using a dielectric material having a thermal expansion coefficient different from a thermal expansion coefficient of the substrate; and
thermal-expansion adjusting portions each produced by filling a prepared-hole with the dielectric material, the prepared-holes being produced at a surface of the substrate, wherein
the surface is partitioned into predetermined blocks, in each of which the thermal-expansion adjusting portions are placed in a layout that minimizes a difference between a thermal expansion coefficient in the block in a length direction and a thermal expansion coefficient in the block in a width direction according to a placement of the wiring through-hole portions in the block.

2. The printed wiring board according to claim 1, wherein the thermal-expansion adjusting portions are placed, according to the placement of the wiring through-hole portions in the block, in a layout that makes a distribution density of the thermal-expansion adjusting portions and the thermal-expansion adjusting portions placed in the block uniform, thereby minimizing the difference between the thermal expansion coefficient in the block in the length direction and the thermal expansion coefficient in the block in the width direction.

3. The printed wiring board according to claim 2, wherein the number of the thermal-expansion adjusting portions placed in the block is adjusted to make the distribution density of the thermal-expansion adjusting portions and the thermal-expansion adjusting portions placed in the block uniform.

4. The printed wiring board according to claim 2, wherein a volume of each of the thermal-expansion adjusting portions placed in the block is adjusted to make the distribution density of the thermal-expansion adjusting portions and the thermal-expansion adjusting portions placed in the block uniform.

5. The printed wiring board according to claim 2, wherein
the blocks are arranged to form columns and rows, and
the thermal-expansion adjusting portions are placed in each of the blocks in a layout that makes per-placed-number column counts, the per-placed-number column counts each being number of columns where a same number of the wiring through-hole portion and the thermal-expansion adjusting portion are placed equal to per-placed-number row counts, the per-placed-number row counts each being number of rows where a same number of the wiring through-hole portion and the thermal-expansion adjusting portion are placed, thereby making the distribution density of the wiring through-hole portions and the thermal-expansion adjusting portions in the block uniform.

6. The printed wiring board according to claim 2, wherein
the blocks are arranged to form columns and rows,
the thermal-expansion adjusting portions are additionally placed in each of the blocks in a layout that makes a spacing between the columns of the wiring through-hole portions and the thermal-expansion adjusting portions equal to a spacing between the rows of the wiring through-hole portions and the thermal-expansion adjusting portions, thereby making the distribution density of the wiring through-hole portion and the thermal-expansion adjusting portion in the block uniform.

7. The printed wiring board according to claim 1, wherein the substrate includes a prepreg that includes, as stuff for controlling thermal expansion, any one of a woven cloth and a non-woven cloth of organic fiber of any one of aramid fiber, poly(p-phenylenebenzobisoxazole), and aromatic polyester fiber.

8. The printed wiring board according to claim 1, wherein the substrate includes a prepreg, the prepreg being a conductive material and including any one of a woven cloth and a non-woven cloth of inorganic fiber of carbon fiber as stuff for controlling thermal expansion.

9. The printed wiring board according to claim 1, wherein the substrate includes a prepreg, the prepreg being a conductive material and including any one of 42 alloy and Kovar as stuff for controlling thermal expansion.

10. The printed wiring board according to claim 8, wherein the dielectric material used in the wiring through-hole portions insulates electrical connection between the conductive material in the substrate and the wiring through-holes.

11. The printed wiring board according to claim 1, wherein the substrate has a product area and an other-than-product area,
the product area is partitioned into the plurality of predetermined blocks, and
the thermal-expansion adjusting portions are placed in the other-than-product area in a layout that makes thermal expansion coefficients in the length direction and in the width direction in the other-than-product area equal to the thermal expansion coefficients in the length direction and in the width direction in the blocks of the product area.

12. The printed wiring board according to claim 11, wherein a test coupon pattern, in which the wiring through-hole portions and the thermal-expansion adjusting portions are placed in a same layout as the layout of the wiring through-hole portions and the thermal-expansion adjusting portions in the blocks of the product area, for product assurance.

13. A method for manufacturing a printed wiring board, the printed wiring board including
wiring through-hole portions where wiring through-holes which each penetrate the substrate from a surface on a front side of the substrate to a surface on a back side of the substrate, the wiring through-hole portions being made using a dielectric material having a thermal expansion coefficient different from a thermal expansion coefficient of the substrate; and
thermal-expansion adjusting portions produced by filling prepared-holes with the dielectric material, the prepared-holes being produced at a surface of the substrate, the surface being partitioned into predetermined blocks, in each of which the thermal-expansion adjusting portions are placed in a layout that minimizes a difference between a thermal expansion coefficient in the block in a length direction and a thermal expansion coefficient in the block in a width direction according to a placement of the wiring through-hole portions in the block, the method comprising:
creating a layout design of the printed wiring board;
drilling the prepared-holes in the thermal-expansion adjusting portions according to the layout design;
filling the prepared-holes with the dielectric material to produce the thermal-expansion adjusting portions;
laminating copper foils on the surfaces of the substrate;
drilling the wiring through through-holes in the thermal-expansion adjusting portions according to the layout design to form the thermal-expansion adjusting portions into the wiring through-hole portions;
plating inner peripheral walls of the wiring through-holes; and
forming a wiring pattern on the substrate.

14. An electronic equipment comprising a printed wiring board including a substrate, the substrate including:
wiring through-hole portions where wiring through-holes which each penetrate the substrate from a surface on a front side of the substrate to a surface on a back side of the substrate, the wiring through-hole portions being made using a dielectric material having a thermal expansion coefficient different from a thermal expansion coefficient of the substrate; and
thermal-expansion adjusting portions each produced by filling a prepared-hole with the dielectric material, the prepared-holes being produced at a surface of the substrate, wherein
the surface is partitioned into predetermined blocks, in each of which the thermal-expansion adjusting portions are placed in a layout that minimizes a difference between a thermal expansion coefficient in the block in a length direction and a thermal expansion coefficient in the block in a width direction according to a placement of the wiring through-hole portions in the block.
